(19) United States
(12) Patent Application Publication
(10) Pub. No.: US 2012/0315745 A1
(43) Pub. Date: Dec. 13, 2012

(54) CRYSTALLINE SILICON FILM FORMING METHOD AND PLASMA CVD APPARATUS

(75) Inventors: Daisuke Katayama, Nirasaki (JP); Minoru Honda, Nirasaki (JP); Masayuki Kohno, Nirasaki (JP); Toshio Nakanishi, Nirasaki (JP)

(73) Assignee: TOKYO ELECTRON LIMITED, Tokyo (JP)

(21) Appl. No.: 13/499,150

(22) PCT Filed: Sep. 28, 2010
(86) PCT No.: PCT/JP2010/066794

§ 371 Date: Apr. 16, 2012

(30) Foreign Application Priority Data
Sep. 30, 2009 (JP) 2009-227639

(51) Int. Cl. H01L 21/20; C23C 16/511

(52) U.S. Cl. 438/488; 118/723 AN; 257/E21.09

(57) ABSTRACT

A high-quality crystalline silicon film can be formed at a high film forming rate by performing a plasma CVD process. In a crystalline silicon film forming method for forming a crystalline silicon film on a surface of a processing target object by using a plasma CVD apparatus for introducing microwave into a processing chamber through a planar antenna having a multiple number of holes and generating plasma, the crystalline silicon film forming method includes generating plasma by exciting a film forming gas containing a silicon compound represented as SiₙH₂ₙ₊₂ (n is equal to or larger than 2) by the microwave; and depositing a crystalline silicon film on the surface of the processing target substrate by performing the plasma CVD process with the plasma.

### TECHNICAL FIELD

The present disclosure relates to a crystalline silicon film forming method, and also relates to a plasma CVD apparatus.

### BACKGROUND ART

Crystalline silicon is a material that can be doped with high density and is widely used for a semiconductor device such as a diode. Conventionally, a thermal CVD method or a plasma CVD method using plasma excited by a high frequency power has been used for manufacturing a crystalline silicon film. So far, in both of the thermal CVD method and the plasma CVD method, in order to suppress a defect of a crystalline silicon film, only monosilane (SiH₄) is used as a source gas for industrial purpose.

In order to increase a film forming rate in the plasma CVD method, it may be effective to increase a flow rate of SiH₄ (source gas) per hour. However, it is known that if the flow rate of SiH₄ per hour is increased, the crystallization degree of the crystalline silicon film is reduced, resulting in degradation of film quality. For the reason, in the plasma CVD method, it has been difficult to form a high-quality crystalline silicon film in a short period of time, which becomes an obstacle to mass production of crystalline silicon films on an industrial scale.

### DISCLOSURE OF THE INVENTION

### Problems to be Solved by the Invention

In view of the foregoing problems, illustrative embodiments provide a method for forming a high-quality crystalline silicon film at a high film forming rate by a plasma CVD method.

### Means for Solving the Problems

In accordance with one aspect of an illustrative embodiment, there is provided a crystalline silicon film forming method for forming a crystalline silicon film on a surface of a processing target object by using a plasma CVD apparatus for introducing microwave into a processing chamber through a planar antenna having a multiple number of holes and generating plasma. The crystalline silicon film forming method includes generating plasma by exciting a film forming gas containing a silicon compound represented as SiₙH₂ₙ₊₂ (n is equal to or larger than 2) by the microwave; and depositing a crystalline silicon film on the surface of the processing target substrate by performing a plasma CVD process with the plasma.

In the crystalline silicon film forming method, the silicon compound may be disilane or trisilane.

In the crystalline silicon film forming method, the film forming gas may contain a rare gas.

In the crystalline silicon film forming method, the film forming gas may contain a hydrogen gas.

In the crystalline silicon film forming method, a volumetric flow rate ratio of the silicon compound to the film forming gas may be in the range of from, e.g., about 0.5% to about 10%.

In the crystalline silicon film forming method, the plasma CVD process may be performed while setting an inner pressure of the processing chamber to be in the range of from, e.g., about 0.1 Pa to about 10.6 Pa.

In the crystalline silicon film forming method, a processing temperature may be set to be in the range of from, e.g., about 250° C. to about 600° C.

In the crystalline silicon film forming method, a microwave power density per unit area of the processing target object may be set to be in the range of from, e.g., about 0.25 W/cm² to about 2.56 W/cm².

In the crystalline silicon film forming method, during the plasma CVD process, a bias voltage may be applied to the processing target object by applying a high frequency power to an electrode embedded in a mounting table for mounting the processing target object thereon.

In accordance with another aspect of an illustrative embodiment, there is provided a plasma CVD apparatus for forming a crystalline silicon film on a processing target object by performing a plasma CVD process. The plasma CVD apparatus include a processing chamber having a top opening for accommodating therein the processing target object; a mounting table, provided within the processing chamber, for mounting thereon the processing target object; a dielectric member that covers the top opening of the processing chamber; a planar antenna, provided on the dielectric member, having a multiple number of holes through which microwave is introduced into the processing chamber; a gas inlet through which a film forming gas is introduced into the processing chamber; an exhaust device configured to evacuate and depressurize the processing chamber; and a controller configured to control the plasma CVD apparatus to perform a crystalline silicon film forming method. Here, the crystalline silicon filing forming method includes generating plasma by exciting a film forming gas introduced into the processing chamber through the planar antenna by the microwave, the film forming gas containing a silicon compound represented as SiₙH₂ₙ₊₂ (n is equal to or larger than 2); and depositing a crystalline silicon film on a surface of the processing target substrate by performing the plasma CVD process with the plasma. Further, the plasma CVD apparatus further includes an electrode embedded in the mounting table; and a high frequency power supply connected to the electrode. Here, the controller may be configured to apply a bias voltage to the processing target object by applying a high frequency power to the electrode during the plasma CVD process.

### Effect of the Invention

In accordance with the crystalline silicon film forming method of the illustrative embodiments, the plasma CVD apparatus configured to generate plasma by introducing a microwave into the processing chamber through the planner antenna having the multiple number of holes is used. In this plasma CVD apparatus, the plasma CVD process is performed by using the film forming gas including the silicon compound represented as SiₙH₂ₙ₊₂ (n is equal to or larger than 2). By using this method, a crystalline silicon film can be formed at a high film forming rate without degrading crystallization degree.

Furthermore, in accordance with the film forming method of the illustrative embodiments, since the crystalline silicon film can be formed at a low temperature equal to or lower than about 600° C., thermal budget can be reduced, and, further, diffusion of dopant can be avoided in the film forming process. Thus, the present illustrative embodiment can be effectively used in a semiconductor manufacturing process.

### BRIEF DESCRIPTION OF THE DRAWINGS

FIG. 1 is a schematic cross sectional view illustrating an example plasma CVD apparatus for forming a crystalline silicon film.

FIG. 2 is a diagram illustrating a structure of a planar antenna.

FIG. 3 is a diagram for describing a configuration of a controller.

FIG. 4 is a graph showing a relationship between a film forming rate of a polysilicon film and a flow rate of a film forming gas.

FIG. 5 is a graph showing a relationship between crystallization degree of a polysilicon film and a flow rate of a film forming gas.

FIG. 6 is a graph showing a relationship between crystal orientation of a polysilicon film and a flow rate of a film forming gas.

FIG. 7 is a graph showing a relationship between crystal orientation of a polysilicon film and a film forming pressure.

FIG. 8 is a graph showing a relationship between crystal orientation of a polysilicon film and a film forming temperature.

FIG. 9 is a graph showing a relationship between crystal orientation of a polysilicon film and a microwave power.

FIG. 10 is a schematic diagram illustrating a configuration of a cross point type memory cell array.

FIG. 11 is a cross sectional view illustrating major parts of the memory cell array of FIG. 10.

FIG. 12 is a diagram for describing a manufacturing process for a diode.

FIG. 13 is a diagram for describing a process subsequent to the process of FIG. 12.

FIG. 14 is a diagram for describing a process subsequent to the process of FIG. 13.

FIG. 15 is a diagram for describing a state in which a polysilicon film to be used as a pin diode is formed by layering.

### EXPLANATION OF CODES

1: Processing chamber
2: Mounting table
3: Supporting member
5: Heater
9: High frequency power supply
12: Exhaust pipe
14: Gas inlet
14a: First gas inlet
14b: Second gas inlet
16: Loading/unloading port
17: Gate valve
18: Gas supply device
19a: Inert gas supply source
19b: Hydrogen gas supply source
19c: Silicon compound gas (Si compound gas) supply source
19d: Dopant gas supply source
19e: Hydrogen gas supply source
24: Exhaust device
27: Microwave introduction device
28: Transmission plate
29: Seal member
31: Planar antenna
32: Microwave radiation hole
37: Waveguide
39: Microwave generator
50: Controller
100: Plasma CVD apparatus
W: Silicon wafer (substrate)

### BEST MODE FOR CARRYING OUT THE INVENTION

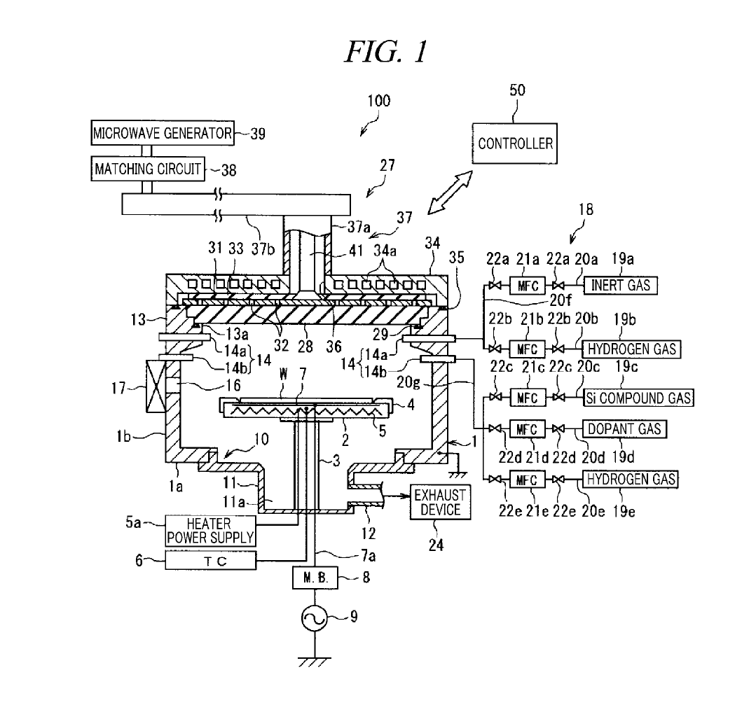

Hereinafter, illustrative embodiments will be described in detail with reference to the accompanying drawings. FIG. 1 is a cross sectional view schematically illustrating a configuration of a plasma CVD apparatus 100 that can be applied to a manufacturing method for a crystalline silicon film in accordance with an illustrative embodiment.

The plasma CVD apparatus 100 is configured as a RLSA (Radial Line Slot Antenna) microwave plasma processing apparatus capable of generating microwave-excited plasma having high density and low electron temperature by introducing a microwave into a processing chamber through a RLSA. In the plasma CVD apparatus 100, a process can be performed by plasma having a density of about 1×10¹⁰/cm³ to about 5×10¹²/cm³ and a low electron temperature of about 0.7 eV to about 2 eV. Accordingly, the plasma CVD apparatus 100 can be used for forming a polysilicon film as a crystalline silicon film by plasma CVD in a manufacturing process of various semiconductor devices.

The plasma CVD apparatus 100 includes, as major components, an airtightly configured processing chamber 1; a gas supply device 18 configured to supply a gas into the processing chamber 1; a gas inlet 14 connected with the gas supply device 18; an exhaust device 24 configured to depressurize and exhaust the inside of the processing chamber 1; a microwave introduction device 27 provided on top of the processing chamber 1 so as to introduce a microwave into the processing chamber 1; and a controller 50 that controls each component of the plasma CVD apparatus 100. Furthermore, the gas supply device 18 may not be provided in the plasma CVD apparatus 100. Instead, an external gas supply device may be connected to the gas inlet 14.

The processing chamber 1 is formed of a substantially cylindrical vessel that is electrically grounded and has a top opening. Instead, the processing chamber 1 may be formed of a prism-shaped vessel. The processing chamber 1 includes a bottom wall 1a and a sidewall 1b made of, e.g., aluminum.

Provided within the processing chamber 1 is a mounting table 2 for horizontally mounting thereon a silicon wafer (hereinafter, simply referred to as a “wafer”) W as a processing target object. The mounting table 2 is made of a highly heat-conductive material, e.g., ceramic such as AlN. The mounting table 2 is supported on a cylindrical supporting member 3 that is upwardly extended from the center of a bottom of an exhaust room 11 and. The supporting member 3 is made of, e.g., ceramic such as AlN.

Further, a cover ring 4 for covering a periphery portion of the mounting table 2 and guiding the wafer W is provided on the mounting table 2. The cover ring 4 is a circular ring-shaped member made of, but not limited to, quartz, AlN, Al₂O₃, SiN, or the like. In order to protect the mounting table 2, the cover ring 4 may be provided so as to cover the entire surface of the mounting table 2.

A resistance heater 5 serving as a temperature control device is embedded in the mounting table 2. The heater 5 is powered by a heater power supply 5a and heats the mounting table 2, so that the wafer W as the processing target substrate is uniformly heated.

Further, a thermocouple (TC) 6 is also provided within the mounting table 2. By measuring a temperature through the thermocouple 6, a heating temperature for the wafer W can be controlled within a range from, e.g., a room temperature to about 900° C.

In addition, the mounting table 2 is also provided with wafer supporting pins (not shown) for elevating the wafer W while supporting the wafer W thereon. Each supporting pin is provided so as to be protruded above and retracted below the surface of the mounting table 2.

Further, an electrode 7 is embedded in a surface side of the mounting table 2. The electrode 7 is positioned between the heater 5 and the surface of the mounting table 2. The electrode 7 is connected with a high frequency power supply 9 for bias application by a power supply line 7a via a matching box (M.B.) 8. By supplying a high frequency power from the high frequency power supply 9 to the electrode 7, a high frequency bias (RF bias) can be applied to the wafer W as a substrate. That is, the electrode 7, the power supply line 7a, the matching box (M.B.) 8, and the high frequency power supply 9 constitute a bias application device. Desirably, the electrode 7 may be made of a material having a thermal expansion coefficient equivalent to that of ceramic such as AlN for forming the mounting table 2. By way of non-limiting example, the electrode 7 may be made of a conductive material such as, but not limited to, molybdenum or tungsten. The electrode 7 is formed in, e.g., a mesh shape, a grid shape or a spiral shape. Desirably, the size of the electrode 7 may be set to be at least equivalent to or slightly larger than the size of the wafer W (By way of example, the electrode 7 may have a size larger than the diameter of the wafer W by about 1 mm to about 5 mm).

A circular opening 10 is formed at a substantially central portion of the bottom wall 1a of the processing chamber 1. The exhaust room 11 is provided at the bottom wall 1a so as to be protruded downward. The exhaust room 11 communicates with the opening 10 and is connected with an exhaust pipe 12. The exhaust room 11 is connected with an exhaust device 24 via the exhaust pipe 12.

A circular ring-shaped plate 13 having a function as a cover body (lid) for opening and closing the processing chamber 1 is provided on top portion of the sidewall 1b of the processing chamber 1. A lower portion of an inner periphery of the plate 13 is protruded inward (toward a space within the processing chamber), and forms a circular ring-shaped supporting portion 13a.

A gas inlet 14 for introducing a processing gas is provided at an upper portion of the processing chamber 1. To elaborate, a first gas inlet 14a having a first gas inlet hole is formed at the plate 13. Further, a second gas inlet 14 having a second gas inlet hole is formed at the sidewall 1b of the processing chamber 1. That is, the first gas inlet 14a and the second gas inlet 14b are arranged in two levels in a vertical direction. The first gas inlet 14a and the second gas inlet 14b are connected with a gas supply device 18 configured to supply a film forming gas or a plasma exciting gas. Furthermore, the first gas inlet 14a and the second gas inlet 14b may be provided in a nozzle shape or a shower shape. Further, the first gas inlet 14a and the second gas inlet 14b may be also provided in a single shower head. Moreover, both the first gas inlet 14a and the second gas inlet 14b may be formed in the sidewall 1b of the processing chamber 1.

A loading/unloading port 16 through which the wafer W is loaded and unloaded between the plasma CVD apparatus 100 and an adjacent transfer chamber (not shown) is formed at the sidewall 1b of the processing chamber 1. Further, a gate valve 17 for opening/closing the loading/unloading port is also provided at the sidewall 1b of the processing chamber 1.

The gas supply device 18 supplies a film forming gas and the like into the processing chamber 1. The gas supply device 18 includes an inert gas supply source 19a, a hydrogen gas supply source 19b, a silicon-compound containing gas (Si compound gas) supply source 19c, a dopant gas supply source 19d and a hydrogen gas supply source 19e. The inert gas supply source 19a and the hydrogen gas supply source 19b are connected to the first gas inlet 14a via gas lines 20a and 20b and a gas line 20f. Further, the silicon compound gas supply source 19c, the dopant gas supply source 19d and the hydrogen gas supply source 19e are connected to the second gas inlet 14b via gas lines 20c, 20d and 20e and a gas line 20g. Further, though not shown, the gas supply device 18 may further include gas supply sources other than those shown in the figure. By way of example, the gas supply device 18 may include a cleaning gas supply source for cleaning the inside of the processing chamber 1, a purge gas supply source for substituting an atmosphere within the processing chamber 1, and so forth.

In accordance with the present illustrative embodiment, a gas of a silicon compound having two or more silicon atoms in a single molecule, more specifically, a gas of a silicon compound represented as SiₙH₂ₙ₊₂ (here, n is equal to or larger than 2) is used as a silicon compound gas serving as a film forming source material. Desirably, the silicon compound gas may be composed of silicon atoms and hydrogen atoms. By way of non-limiting example, disilane (Si₂H₆) or trisilane (Si₃H₈) may be used as the silicon compound gas. Further, a combination of two or more kinds of these gases may also be used.

Further, besides the silicon compound gas, an inert gas, a hydrogen gas, a dopant gas and so forth can also be used as the film forming gas. Since the inert gas and the hydrogen gas are plasma-generating gases for allowing plasma to be stably generated within the processing chamber 1, it may be desirable to mix these gases in the film forming gas.

By way of non-limiting example, a rare gas may be used as the inert gas. The rare gas serving as a plasma-exciting gas contributes to stable generation of the plasma. By way of example, an Ar gas, a Kr gas, a Xe gas, a He gas or the like may be used as the rare gas.

When forming an n-type polysilicon film, PH₃, AsH₃ or the like may be used as the dopant gas. Meanwhile, when forming a p-type polysilicon film, B₂H₆ or the like may be used as the dopant gas.

The inert gas and the hydrogen gas are supplied into the gas line 20f from the inert gas supply source 19a and the hydrogen gas supply source 19b through the gas lines 20a and 20f, respectively. Then, the inert gas and the hydrogen gas are flown together to the first gas inlet 14a through the gas line 20f and are introduced into the processing chamber 1 through the first gas inlet 14a. Meanwhile, the silicon compound gas, the dopant gas and the hydrogen gas are supplied into the gas line 20g from the silicon compound gas supply source 19c, the dopant gas supply source 19d and the hydrogen gas supply source 19e through the gas lines 20c, 20d and 20e, respectively. Then, the silicon compound gas, the dopant gas and the hydrogen gas are flown together to the second gas inlet 14b through the gas line 20g and are introduced into the processing chamber 1 through the second gas inlet 14b. Mass flow controllers 21a to 21e are provided at the gas lines 20a to 20e connected to the respective gas supply sources, respectively. Also, opening/closing valves 22a to 22e are provided upstream and downstream of the mass flow controllers 21a to 21e at the gas lines 20a to 20e, respectively. With this configuration of the gas supply device 18, it is possible to control a switchover and a flow rate of the supplied gas. Furthermore, the inert gas for plasma excitation such as Ar and the hydrogen gas are nothing more than examples, and, they may not necessarily be supplied concurrently with the film forming gas.

The exhaust device 24 includes a high-speed vacuum pump such as a turbo molecular pump. As mentioned above, the exhaust device 24 is connected with the exhaust room 11 of the processing chamber 1 through the exhaust pipe 12. By operating the exhaust device 24, a gas within the processing chamber 1 uniformly flows in a space 11a within the exhaust room 11 and is exhausted from the exhaust room 11 to the outside through the exhaust pipe 12. Accordingly, the inside of the processing chamber 1 can be depressurized to, e.g., about 0.133 Pa at a high speed.

Now, a configuration of the microwave introduction device 27 will be explained. The microwave introduction device 27 includes, as major components, a transmission plate 28; a planar antenna 31; a wavelength shortening member 33; a cover member 34; a waveguide 37; and a microwave generator 39. Here, the microwave introduction device 27 is configured as a plasma generation device that generates plasma by introducing a microwave into the processing chamber 1.

The transmission plate 28 serving as a dielectric member is placed on the supporting portion 13a that is protruded toward an inner peripheral side of the plate 13. The transmission plate 28 is made of a dielectric material that transmits microwave. For example, the transmission plate 28 may be made of quartz or ceramic such as Al₂O₃ or AlN. Especially, to be used as the plasma CVD device, it may be desirable that the transmission plate 28 is made of ceramic such as Al₂O₃ or AlN. A gap between the transmission plate 28 and the supporting portion 13a is airtightly sealed by a seal member 29 provided therebetween. Accordingly, the top opening of the processing chamber 1 is closed by the transmission plate 28 via the plate 13. As a result, the inside of the processing chamber 1 can be airtightly sealed.

The planar antenna 31 is provided above the transmission plate 28 so as to face the mounting table 2. The planar antenna 31 has a circular plate shape. However, the shape of the planar antenna 31 may not be limited to the circular plate shape. For example, the planar antenna 31 may have a rectangular plate shape. The planar antenna 13 is fixed on a top end of the plate 13.

The planar antenna 31 may be made of, but not limited to, an aluminum plate or a nickel plate, a SUS plate or a copper plate coated with gold or silver. The planar antenna 31 has a multiple number of slot-shaped microwave radiation holes 32 and the microwave is radiated through the microwave radiation holes 32. The microwave radiation holes 32 are formed through the planar antenna 31 in a certain pattern.

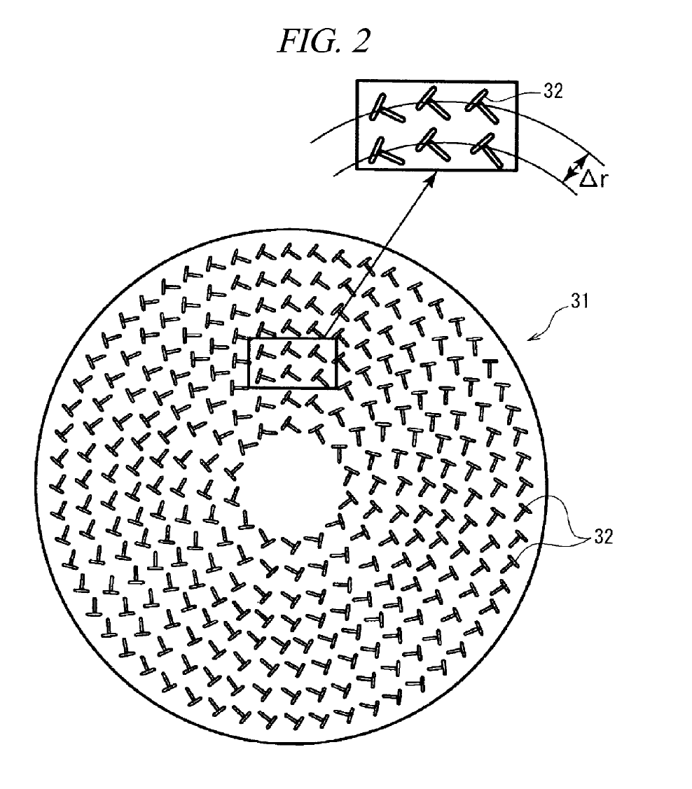

By way of example, as illustrated in FIG. 2, each microwave radiation hole 32 has a narrow elongated rectangular shape (slot shape) and every two adjacent microwave radiation holes make a pair. Typically, the two adjacent microwave radiation holes 32 in each pair are arranged in an “L” shape. The microwave radiation holes 32 combined in the certain shape (e.g., L shape) in this way are concentrically arranged.

A length of each of the microwave radiation holes 32 and an arrangement interval therebetween depend on a wavelength (λg) of the microwave. For example, the microwave radiation holes 32 may be spaced apart from each other at an interval ranging from λg/4 to λg. In FIG. 2, Δr indicates the interval between the adjacent microwave radiations holes 32 that are concentrically arranged. Further, the microwave radiations holes 32 may have another shape, e.g., a circular shape, an arc shape, or the like. Further, the microwave radiation holes 32 may not be arranged concentrically but may be arranged in another pattern, e.g., a spiral pattern, a radial pattern or the like.

The wavelength shortening member 33 is provided on a top surface of the planar antenna 31. The wavelength shortening member 33 is made of a material having a dielectric constant greater than that of a vacuum, such as, but not limited to, quartz, Al₂O₃, AlN or resin. A wavelength of the microwave becomes longer in the vacuum. The wavelength shortening member 33 serves to shorten the wavelength of the microwave so as to adjust plasma.

Although the planar antenna 31 may be in contact with or spaced apart from the transmission plate 28 and the wavelength shortening member 33, it may be desirable that the planar antenna 31 is in contact with the transmission plate 28 and the wavelength shortening member 33.

The cover member 34 is placed on the plate 13 so as to cover the planar antenna 31 and the wavelength shortening member 33. The cover member 34 may be made of a metal material such as, but not limited to, aluminum or stainless steel. The plate 13 and the cover member 34 are airtightly sealed against each other by a seal member 35. A cooling water path 34a is formed within the cover member 34. By flowing and circulating cooling water through the cooing water path 34a, the cover member 34, the wavelength shortening member 33, the planar antenna 31, and the transmission plate 28 can be cooled. Further, the cover member 34 is grounded.

An opening 36 is formed at the center of a top wall (ceiling) of the cover member 34, and one end of the waveguide 37 is connected to the opening 36. The other end of the waveguide 37 is connected to the microwave generator 39 that generates a microwave via a matching circuit 38.

The waveguide 37 includes a coaxial waveguide 37a having a circular cross section and upwardly extending from the opening 36 of the cover member 34; and a rectangular waveguide 37b extending in a horizontal direction and connected to an upper end of the coaxial waveguide 37a.

An inner conductor 41 is extended in the center of the coaxial waveguide 37a. A lower end of the inner conductor 41 is connected and fixed to the center of the planar antenna 31. In this configuration, microwave can be radially propagated to the planar antenna 31 via the inner conductor 41 of the coaxial waveguide 37a efficiently and uniformly.

By the microwave introduction device 27 configured as described above, the microwave generated by the microwave generator 39 is propagated to the planar antenna 31 through the waveguide 37 and then is introduced into the processing chamber 1 through the transmission plate 28. Desirably, a microwave having a frequency of, e.g., about 2.45 GHz may be used, and, alternatively, about 8.35 GHz or about 1.98 GHz may be used.

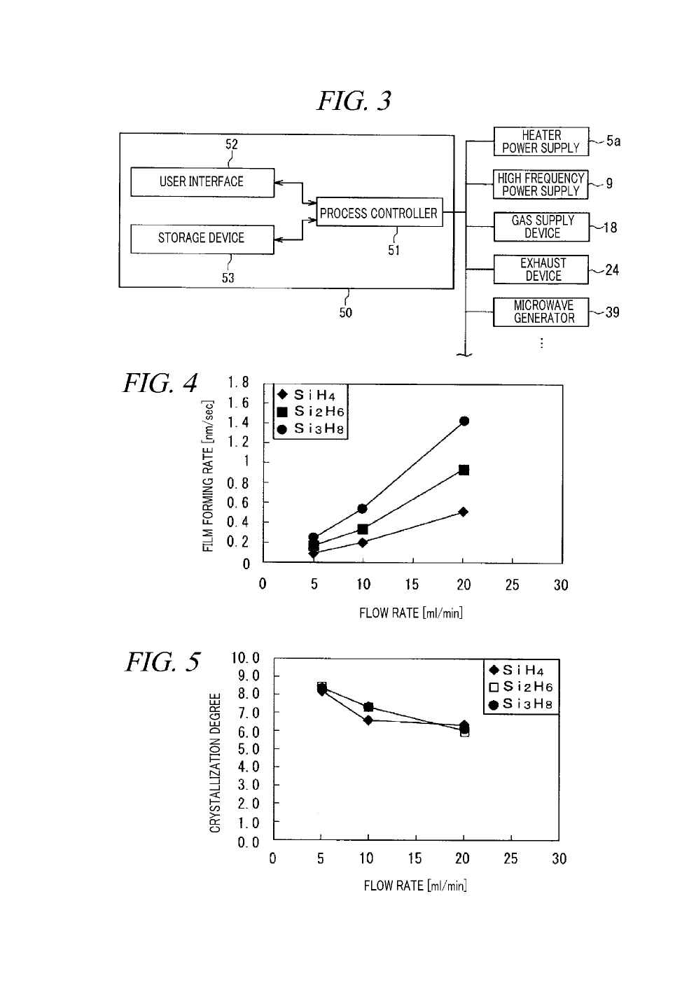

Each component of the plasma CVD apparatus 100 is connected to and controlled by the controller 50 having a computer. By way of example, the controller 50 may include, as shown in FIG. 3, a process controller 51 having a CPU; a user interface 52; and a storage device 53. The user interface 52 and the storage device 53 are connected with the process controller 51. The process controller 51 controls overall operations of respective components (e.g., the heater power supply 5a, the high frequency power supply 9, the gas supply device 18, the exhaust device 24, the microwave generator 39, and so forth) of the plasma CVD apparatus 100 related to processing conditions such as temperature, pressure, gas flow rates, microwave power, high frequency power for bias application, and so forth.

The user interface 52 includes a key board through which a process manager inputs a command to manage the plasma CVD apparatus 100; and a display that visually displays an operational status of the plasma CVD apparatus 100. Further, the storage device 53 stores a control program (software) for implementing various processes performed in the plasma CVD apparatus 100 under the control of the process controller 51; and recipes that store processing condition data.

If necessary, in response to an instruction from the user interface 52, a certain recipe is retrieved from the storage device 53 and executed by the process controller 51. As a result, a required process is performed in the plasma CVD apparatus 100 under the control of the process controller 51. Further, the control program or the recipe including the processing condition data may be used while being stored in a computer-readable storage medium such as a CD-ROM, a hard disk, a flexible disk, a flash memory, a DVD or a blue-ray disk. Alternatively, the control program or the recipe may be used on-line by being received from another apparatus through, e.g., a dedicated line, whenever necessary.

Now, a process for depositing a polysilicon film by a plasma CVD method using the RLSA plasma CVD apparatus 100 will be explained. First, after the gate valve 17 is opened, a wafer W is loaded into the processing chamber 1 through the loading/unloading port 16 and mounted on the mounting table 2. Then, while evacuating and depressurizing the inside of the processing chamber 1, a silicon compound gas, a hydrogen gas and/or an inert gas are introduced into the processing chamber 1 from the inert gas supply source 19a, the hydrogen gas supply source 19b, and the silicon compound gas supply source 19c, and the hydrogen gas supply source 19e through the first gas inlet 14a and the second gas inlet 14b at certain flow rates. At this time, if necessary, a dopant gas may also be supplied into the processing chamber from the dopant gas supply source 19d. Then, the inner pressure of the processing chamber 1 is controlled to a preset pressure.

Here, desirable processing conditions (a processing pressure, a flow rate of a film forming gas and a film forming temperature) in the plasma CVD process will be described. Desirably, the processing pressure may be in the range from, e.g., about 0.1 Pa to about 10.6 Pa, and, more desirably, the processing pressure may be in the range from, e.g., about 0.1 Pa to about 5.3 Pa. The processing pressure needs to be set to be as low as possible. The lower limit, about 0.1 Pa, of the processing pressure is set in consideration of restriction in the apparatus (limitation in high vacuum). If the processing pressure exceeds about 10.6 Pa, the crystallization degree of polysilicon may be deteriorated, resulting in degradation of film quality. Thus, it is desirable that the processing pressure does not exceed about 10.6 Pa.

Desirably, a volumetric flow rate ratio of the silicon compound gas such as a Si₂H₆ gas to a total film forming gas (i.e., a percentage of a flow rate of the silicon compound gas to the total film forming gas) is set to be in the range from, e.g., about 0.5% to about 10%, and, more desirably, in the range from, e.g., about 1% to about 5%. More desirably, the volumetric flow rate ratio of the silicon compound gas is selected in the range from, e.g., about 1.25% to about 2.5%. If the volumetric flow rate ratio of the polysilicon compound gas is smaller than about 0.5%, a sufficient film forming rate may not be obtained. If the volumetric flow rate ratio of the polysilicon compound gas exceeds about 10%, a film quality may be degraded. The flow rate of the polysilicon compound gas may be set to range from, e.g., about 1 mL/min (sccm) to about 100 mL/min (sccm), more desirably, from, e.g., about 1 mL/min (sccm) to about 20 mL/min (sccm) so as to obtain the flow rate ratio of the polysilicon compound gas as specified above.

It is desirable that the film forming gas contains the hydrogen gas as well as the silicon compound gas. Hydrogen has a property that it is introduced into a defect in a crystalline silicon film to restore crystal. Accordingly, by adding the hydrogen gas to the film forming gas, crystallinity of the crystalline silicon film can be improved, resulting in improving the film quality thereof. Desirably, a volumetric flow rate ratio of the hydrogen gas to the total film forming gas (i.e., a percentage of a flow rate of the H₂ gas to the total film forming gas) is set to be in the range from, e.g., about 90% to about 99.5%, and, more desirably, in the range from, e.g., about 95% to about 99%. More desirably, the volumetric flow rate ratio of the hydrogen gas is set to be in the range from, e.g., about 97.5% to about 98.75%. Furthermore, the flow rate of the hydrogen gas may be set to range from, e.g., about 10 mL/min (sccm) to about 1000 mL/min (sccm), more desirably, from, e.g., about 50 mL/min (sccm) to about 500 mL/min (sccm) so as to obtain the volumetric flow rate ratio of the hydrogen gas as specified above.

Moreover, in order to stably generate plasma, it is desirable to add an inert gas such as Ar gas in addition to the silicon compound gas and the hydrogen gas. In such a case, desirably, a volumetric flow rate ratio of the inert gas to the total film forming gas (i.e., a percentage of a flow rate of, e.g., the Ar gas to the total flow rate of the film forming gas) is set to be in the range from, e.g., about 1% to about 10%, and, more desirably, in the range from, e.g., about 1% to about 5%. Further, the flow rate of the inert gas may be set to range from, e.g., about 2 mL/min (sccm) to about 100 mL/min (sccm), more desirably, from, e.g., about 2 mL/min (sccm) to about 50 mL/min (sccm) so as to obtain the volumetric flow rate ratio of the inert gas as specified above.

Further, when using the inert gas instead of the hydrogen gas (that is, when using the silicon compound gas and the inert gas), it may be desirable that the flow rate of the inert gas is in the range of from, e.g., about 100 mL/min (sccm) to about 1500 mL/min (sccm).

Since a plasma CVD processing temperature reduces thermal budge and suppresses diffusion of impurities, the temperature of the mounting table 2 needs to be set to be equal to or lower than, e.g., about 600° C. Desirably, the temperature of the mounting table 2 is set to be in the range from, e.g., about 250° C. to about 600° C., more desirably, in the range from, e.g., about 250° C. to about 500° C.

Subsequently, a microwave of a preset frequency, e.g., about 2.45 GHz generated by the microwave generator 39 is guided to the waveguide 37 via the matching circuit 38. The microwave guided to the waveguide 37 is supplied to the planar antenna 31 through the internal conductor 41 after passing through the rectangular waveguide 37b and the coaxial waveguide 37a in sequence. That is, the microwave propagates within the coaxial waveguide 37a toward the planar antenna 31. Then, the microwave is radiated into a space above the wafer W within the processing chamber 1 through the slot-shaped microwave radiation holes 32 of the planar antenna 31 via the transmission plate 28. At this time, as the microwave power increases, the crystallization degree of a polysilicon film formed may also be increased. Thus, desirably, a microwave power density per unit area is set to be in the range of from, e.g., about 0.25 W/cm² to about 2.56 W/cm², and the microwave power is appropriately selected as required from the range from, e.g., about 500 W to about 5000 W so as to obtain the microwave power density as specified above. Here, the upper limit of the microwave power, i.e., about 5000 W is set in consideration of restriction in the apparatus. If possible, it may be also possible to supply the microwave at a power level higher than the upper limit.

By the microwave radiated into the processing chamber 1 from the planar antenna 31 through the transmission plate 28, an electromagnetic field is formed within the processing chamber 1, and the silicon compound gas, the hydrogen gas, the inert gas, and/or the dopant gas (if added) are excited into plasma, respectively. In the plasma, the source gas is dissociated efficiently, and a polysilicon film is deposited by reaction of active species such as SiₚH_{q} or SiH_{q} (p and q denote arbitrary numbers, hereinafter).

When necessary, while the plasma CVD process is being performed, a high frequency power of the preset frequency and magnitude may be applied to the electrode 7 of the mounting table 2 from the high frequency power supply 9, and a high frequency bias voltage (hereinafter, simply referred to as a “RF bias”) may be supplied to the wafer W. In the plasma CVD apparatus 100, since the electron temperature of the plasma can be maintained low, damage to the film may be reduced even if the RF bias is applied. Furthermore, since the application of the RF bias in a certain range allows Si ions in the plasma to be attracted toward the wafer W, the crystallization degree can be improved. As a result, the quality of the polysilicon film can be improved and the film forming rate can be more increased. In this case, it is desirable to set the frequency of the high frequency power from the high frequency power supply 9 to be in the range from, e.g., about 400 kHz to about 60 MHz, and, more desirably, in the range from, e.g., about 450 kHz to about 20 MHz. As for the high frequency power, a power density per unit area of the wafer W is set to be in the range from, e.g., about 0.012 W/cm² to about 0.585 W/cm² and, more desirably, in the range from, e.g., about 0.012 W/cm² to about 0.234 W/cm². Further, the RF bias may be applied to the electrode 7 in order to obtain the microwave power density as specified above. Here, it is desirable that the high frequency power is set to range from, e.g., about 10 W to about 200 W, more desirably, from, e.g., about 10 W to about 200 W.

The above-mentioned conditions are stored in the storage device 53 of the controller 50 as a recipe. As the process controller 51 reads out the recipe and sends control signals to each component of the plasma CVD apparatus 100 such as the gas supply device 18; the exhaust device 24; the microwave generator 39; the heater power supply 5a; and the high frequency power supply 9, the plasma CVD process is implemented under the required conditions.

Now, conditions required for the plasma CVD process will be explained with reference to experimental data on the basis of the illustrative embodiments.

(Experiment 1)

SiH₄, Si₂H₆ and Si₃H₈ gases are used as silicon compound gases, and an Ar gas is used as a plasma generating gas. In the plasma CVD apparatus 100, formation of a polysilicon film is performed under the following plasma CVD conditions while varying a flow rate of a film forming gas. Film forming rates and crystallization degrees of polysilicon films formed under each of the following conditions are shown in FIGS. 4 and 5. Here, the crystallization degree is obtained by dividing a signal intensity of crystalline silicon (about 520 nm) of a spectrum analyzed by Raman spectroscopy by a signal intensity of amorphous silicon (about 480 nm).

[Plasma CVD Conditions]

Processing temperature (mounting table): about 400° C.

Microwave power: about 3000 W

Processing pressure: about 5.3 Pa

Silane-based gas flow rate: about 5 mL/min (sccm), about 10 mL/min (sccm) or about 20 mL/min (sccm)

Ar gas flow rate: a sum of the Ar gas and the silane-based gas is set to be about 800 mL/min (sccm)

As can be seen from FIG. 4, although the film forming rate tends to increase in proportion to the flow rate of any of the above silicon compound gases, the film forming rate is found to be highest when the Si₃H₈ gas is used and lowest when the SiH₄ gas is used. To be more specific, the film forming rate of Si₃H₈ is about three times as high as the film forming rate of SiH₄, and the film forming rate of Si₂H₆ is about twice as high as the film forming rate of SiH₄. Further, as can be seen from FIG. 5, although the crystallization degree tends to slightly decrease with the rise of the flow rate of any of the silicon compound gases, there is found little difference among the gases. That is, substantially same film qualities are obtained.

Referring to FIG. 6, there is shown a relationship between flow rates of SiH₄ and Si₂H₆ and ratios (%) obtained by normalizing signal intensities of crystal orientation <220> by thicknesses of the polysilicon films after XRD-analyzing polysilicon films. Here, the polysilicon film is formed by using SiH₄ and Si₂H₆ as silicon compounds under the above-specified conditions and XRD-analyzed. Further, in FIG. 6, film forming rates (right gradation of a vertical axis) are also specified. As a result, it is shown that the result of the XRD-analyzing in FIG. 6 has a similar tendency of the Raman spectroscopy. In both cases of using SiH₄ and Si₂H₆, the ratios of the crystal orientation <220> tend to decrease slightly with the rise of the film forming rates of SiH₄ and Si₂H₆. However, there is found little difference between the silicon compounds, and substantially same film qualities are obtained. However, the film forming rate of Si₂H₆ is found to be much higher than the film forming rate of SiH₄, i.e., about twice as high as the film forming rate of SiH₄.

The above-mentioned results indicate that it is more advantageous to use Si₂H₆ and Si₃H₈, as compared to SiH₄. In such a case, a volumetric flow rate ratio of the silicon compound gas (i.e., a percentage of a flow rate of the silicon compound gas to the total film forming gas) needs to be set to range from, e.g., about 1.25% to about 2.5%. Accordingly, it is proved that by using a silicon compound gas having two or more atoms in a single molecule, a film forming rate can be improved greatly without degrading crystallization degree of a polysilicon film.

(Experiment 2)

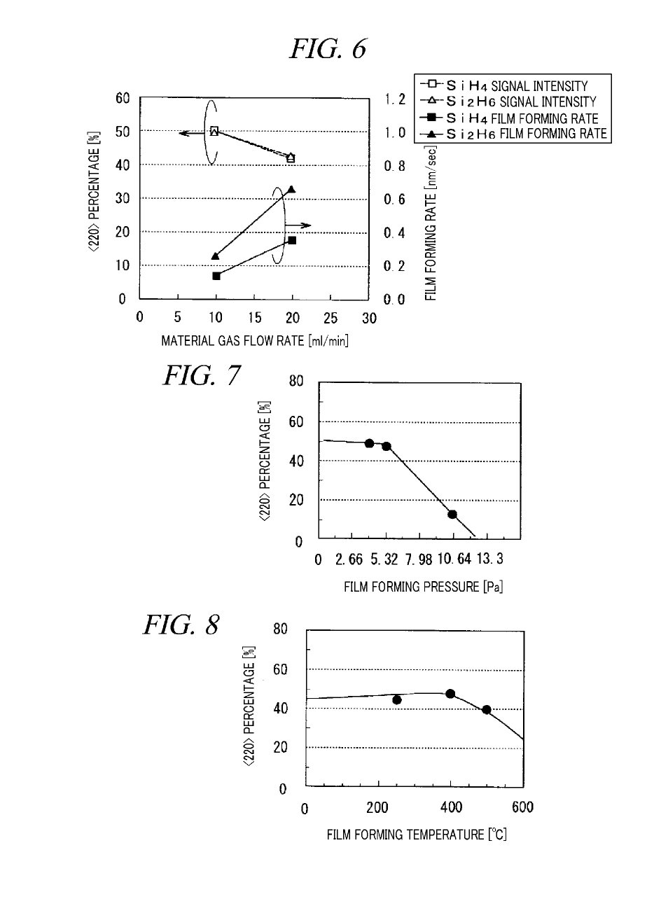

Polysilicon films are formed in the plasma CVD apparatus 100 by using Si₂H₆ as a silicon compound and a H₂ gas as a plasma generating gas under the following plasma conditions. Thereafter, the polysilicon films formed under the respective conditions are analyzed by XRD. Then, an effect of a film forming pressure, a film forming temperature and a microwave power on film qualities are investigated on the basis of ratios (%) of the crystal orientation <220> obtained by normalizing signal intensities of crystal orientation <220> by the thicknesses of the polysilicon films. The results are provided in FIGS. 7 to 9.

[Plasma CVD Conditions]

Processing temperature (mounting table): about 2500, about 4000, or about 500° C.

Microwave power: about, 2000 W, about 3000 W or about 4000 W

Processing pressure: about 4 Pa, about 5.3 Pa or about 10.6 Pa

Silane-based gas flow rate: about 5 mL/min (sccm)

H₂ gas flow rate: a sum of the silane-based gas and the H₂ gas is set to be about 400 mL/min (sccm)

FIG. 7 shows an effect of the film forming pressure. Although the ratio of crystal orientation <220> hardly changes while the pressure is varied from about 4 Pa to about 5.3 Pa, the ratio of crystal orientation <220> is greatly decreased at a pressure of about 10 Pa. Accordingly, it is deemed to be desirable that the film forming pressure needs to be set to be equal to or lower than, e.g., about 10.6 Pa, and, more desirably, to be equal to or lower than, e.g., about 5.3 Pa.

FIG. 8 shows an effect of a film forming temperature (mounting table temperature). The ratio of the crystal orientation <220> hardly changes at the temperatures of about 250° C., about 400° C. and about 500° C., and there is found no significant difference. However, since the ratio of the crystal orientation <220> tends to be decreased if the film forming temperature exceeds about 500° C., it is deemed to be desirable that the upper limit of the film forming temperature is set to about 600° C. Accordingly, it is desirable that the film forming temperature is set to be in the range from, e.g., about 250° C. to about 600° C., and, more desirably, in the range from, e.g., about 250° C. to about 500° C.

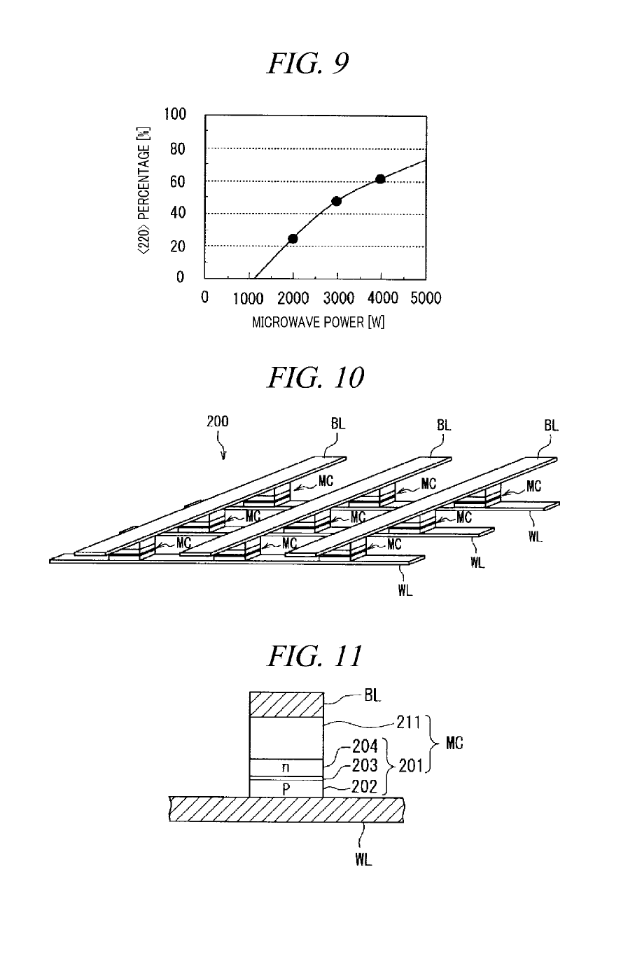

FIG. 9 shows an effect of a microwave power. It is proved that the ratio of the crystal orientation <220> is increased by setting the microwave power to be large, ranging from, e.g., about 2000 W to about 4000 W. That is, FIG. 9 implies that the crystallization degree can be improved as the microwave power increases. Accordingly, it is deemed to be desirable that the microwave power is set to be in the range from, e.g., about 2000 W to about 5000 W, and, more desirably, in the range from, e.g., about 3000 W to about 5000 W.

[Application Example to the Manufacture of Nonvolatile Memory Device]

Now, Referring to FIG. 10 to FIG. 15, it is explained that an example in which the manufacturing method for the crystalline silicon film in accordance with the illustrative embodiment is applied to a manufacturing process of a nonvolatile memory device. FIG. 10 is a schematic configuration view of a cross point type memory cell 200. In the memory cell array 200, a multiple number of bit lines (BL) (3 BLs in FIG. 10) and a multiple number of word lines (WL) (3 WLs in FIG. 10) are provided, and memory cells (MC) are located in intersection points of the bit lines and word lines.

FIG. 11 is a cross sectional view illustrating major parts of the memory cell array 200 of FIG. 10 and shows a detailed structure of a memory cell MC. The memory cell MC is implemented by a circuit structure having a diode 201 connected with a memory device 211 in series. The diode 201 is a pin diode and includes a p-type silicon layer 202, an intrinsic silicon layer 203 and an n-type silicon layer 204.

The memory device 211 may have, e.g., a TMR (Tunneling magnetoresistance) structure in which a ferromagnetic layer and a non-ferromagnetic layer are layered. Here, the ferromagnetic layers may be made of a material (e.g., a transition metal oxide such as PrCaMnO) of which resistance is varied by an electrical stress in a resistive random access memory (RRAM); a material (e.g., GeSeTe) of which phase is varied by a thermal stress from an electric current in a phase-change memory (PRAM); a ferroelectric material (e.g., lead zirconate titanate, strontium/Bismuth/tantalum complex oxide, etc.) in a ferroelectric memory (FeRAM); a transition metal elements, e.g., Fe, Co, Ni, CoFe, NiFe or an alloy thereof in a magnetic memory (MRAM).

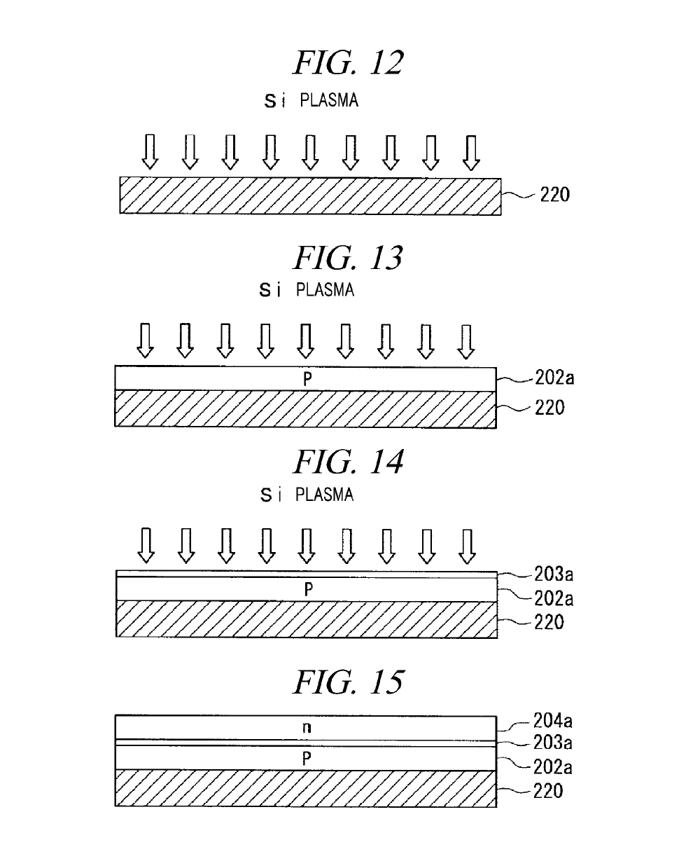

The polysilicon film forming method in accordance with the illustrative embodiment may be applicable to the manufacture of the diode 201 of the cross point type memory cell array 200. As illustrated in FIGS. 12 and 13, a polysilicon layer 202a (a portion to be the p-type silicon layer 202) is formed on a lower electrode layer 220 (to be used as a word line (WL)) by the plasma CVD apparatus 100 by using a film forming gas. Here, the film forming gas contains a silicon compound having two or more silicon atoms in a single molecule and the lower electrode layer 220 is provided on a non-illustrated interlayer insulating film. In this plasma CVD process, a dopant gas such as B₂H₆ is supplied from the dopant gas supply source 29d.

Subsequently, as depicted in FIGS. 13 and 14, a polysilicon layer 203a (a portion to be used as the intrinsic silicon layer 203) is formed on the polysilicon layer 202a by the plasma CVD apparatus 100 while using a film forming gas. Here, the film forming gas contains a silicon compound having two or more silicon atoms in a single molecule.

Thereafter, as shown in FIGS. 14 and 15, a polysilicon layer 204a (a portion to be used as the n-type silicon layer 204) is formed on the polysilicon layer 203a by the plasma CVD apparatus 100 while using a film forming gas. Here, the film forming gas contains a silicon compound gas having two or more atoms in a single molecule. In this plasma CVD process, a dopant gas such as PH₃ is supplied from the dopant gas supply source 19d.

Through the above-described process, the polysilicon layer 202a to be used as the p-type silicon layer 202, the polysilicon layer 203a to be used as the intrinsic silicon layer 203 and the polysilicon layer 204a to be used as the n-type silicon layer 204 can be formed in sequence. Afterward, by forming a material film to be used as the memory element 211 on the polysilicon film 204a and etching the material film, the memory cell MC having the multilayer structure as illustrated in FIG. 11 can be obtained.

By using the manufacturing method in accordance with the illustrative embodiment, it is possible to form the polysilicon layers 202a, 203a and 204a having high quality and high crystallization degree at a high film forming rate. Moreover, in the method in accordance with the illustrative embodiment, by using the plasma CVD apparatus 100 of a type that generates plasma by introducing a microwave into the processing chamber through the planar antenna, it is possible to form the polysilicon films 202a, 203a and 204a at a low temperature equal to or lower than about 600° C. As a result, diffusion of dopant does not occur during the film forming process. Further, typically, by forming the memory cell array 200 to have the multilayer structure as depicted in FIG. 10, degree of integration can be improved. For the purpose, the diode 201 (pin diode) composed of the p-type silicon layer 202, the intrinsic silicon layer 203 and the n-type silicon layer 204 needs to be formed as thin as possible. When forming the polysilicon layers 202a, 203a and 204a by a thermal CVD method, however, it is difficult to obtain thin films and dopant diffuses due to high temperature. In accordance with the method in accordance with the illustrative embodiment, it is possible to form thin polysilicon films 202a, 203a and 204a and. Furthermore, since the film formation is performed at a relatively low temperature, diffusion of dopant can be avoided. Thus, it is advantageous to use the method in accordance with the present illustrative embodiment.

While various aspects of the present illustrative embodiment have been described herein, it is possible to modify the various aspects, not limited to the above-described illustrative embodiment. For example, in the above-described embodiment, although the present method is applied to the manufacturing process of the cross point type nonvolatile memory device, the illustrative embodiment may not be limited thereto and can be widely applied to various semiconductor manufacturing processes in which a high-quality crystalline silicon film needs to be formed at a high film forming rate.

What is claimed is:

1. A crystalline silicon film forming method for forming a crystalline silicon film on a surface of a processing target object by using a plasma CVD apparatus for introducing microwave into a processing chamber through a planar antenna having a multiple number of holes and generating plasma, the method comprising:
generating plasma by exciting a film forming gas containing a silicon compound represented as SiₙH₂ₙ₊₂ (n is equal to or larger than 2) by the microwave; and
depositing a crystalline silicon film on the surface of the processing target substrate by performing a plasma CVD process with the plasma.

2. The film forming method of claim 1, wherein the silicon compound is disilane or trisilane.

3. The film forming method of claim 1, wherein the film forming gas contains a rare gas.

4. The film forming method of claim 1, wherein the film forming gas contains a hydrogen gas.

5. The film forming method of claim 1, wherein a volumetric flow rate ratio of the silicon compound to the film forming gas is in the range of from, e.g., about 0.5% to about 10%.

6. The film forming method of claim 1, wherein the plasma CVD process is performed while setting an inner pressure of the processing chamber to be in the range of from, e.g., about 0.1 Pa to about 10.6 Pa.

7. The film forming method of claim 1, wherein a processing temperature is set to be in the range of from, e.g., about 250° C. to about 600° C.

8. The film forming method of claim 1, wherein a microwave power density per unit area of the processing target object is set to be in the range of from, e.g., about 0.25 W/cm² to about 2.56 W/cm².

9. The film forming method of claim 1, wherein during the plasma CVD process, a bias voltage is applied to the processing target object by applying a high frequency power to an electrode embedded in a mounting table for mounting the processing target object thereon.

10. A plasma CVD apparatus for forming a crystalline silicon film on a processing target object by performing a plasma CVD process, the apparatus comprising:
a processing chamber for accommodating therein the processing target object, the processing chamber having a top opening;
a mounting table, provided within the processing chamber, for mounting thereon the processing target object;
a dielectric member that covers the top opening of the processing chamber;
a planar antenna, provided on the dielectric member, having a multiple number of holes through which microwave is introduced into the processing chamber;
a gas inlet through which a film forming gas is introduced into the processing chamber;
an exhaust device configured to evacuate and depressurize the processing chamber; and
a controller configured to control the plasma CVD apparatus to perform a crystalline silicon film forming method,
the crystalline silicon filing forming method comprising:
generating plasma by exciting a film forming gas introduced into the processing chamber through the planar antenna by the microwave, the film forming gas containing a silicon compound represented as SiₙH₂ₙ₊₂ (n is equal to or larger than 2); and
depositing a crystalline silicon film on a surface of the processing target substrate by performing the plasma CVD process with the plasma.

11. The plasma CVD apparatus of claim 10, further comprising:
an electrode embedded in the mounting table; and
a high frequency power supply connected to the electrode,
wherein the controller is configured to apply a bias voltage to the processing target object by applying a high frequency power to the electrode during the plasma CVD process.
